(19) United States
(12) Patent Application Publication
(10) Pub. No.: US 2022/0115367 A1
(43) Pub. Date: Apr. 14, 2022

(54) TECHNIQUES FOR DIE TILING

(71) Applicant: Intel Corporation, Santa Clara, CA (US)

(72) Inventors: Srinivas PIETAMBARAM, Chandler, AZ (US); Gang DUAN, Chandler, AZ (US); Deepak KULKARNI, Chandler, AZ (US)

(21) Appl. No.: 17/556,660

(22) Filed: Dec. 20, 2021

Related U.S. Application Data
(63) Continuation of application No. 15/949,141, filed on Apr. 10, 2018.

(51) Int. Cl. H01L 25/00; H01L 23/48; H01L 23/538; H01L 23/29; H01L 21/683; H01L 23/31

(52) U.S. Cl. CPC H01L 25/50; H01L 23/481; H01L 23/5381; H01L 23/5384; H01L 23/5389; H01L 2221/68345; H01L 21/6835; H01L 23/3121; H01L 2221/68359; H01L 2221/68309; H01L 23/293

(57) ABSTRACT

Techniques are provided for fine node heterogeneous-chip packages. In an example, a method of making a heterogeneous-chip package can include coupling electrical terminals of a first side of a first base die to electrical terminals of a first side of a second base die using a silicon bridge, forming an organic substrate about the silicon bridge and adjacent the first sides of the first and second base dies, and coupling a fine node die to a second side of at least one of the first base die or the second base die.

This application is a continuation of U.S. patent application Ser. No. 15/949,141, filed on Apr. 10, 2018, the entire contents of which is hereby incorporated by reference herein.

### TECHNICAL FIELD

This document pertains generally, but not by way of limitation, to die interconnections, and more particularly to providing large heterogeneous-die packages using integrated die bridges.

### BACKGROUND

Conventional die manufacturing techniques are being pushed to their limits for size of a monolithic die, yet applications are yearning for capabilities that are possible for large dimensional integrated circuits using the latest technology such as 7 nm gate lengths. As monolithic dies have become bigger, small differences that can be overlooked for smaller dies, cannot be compensated for and can often significantly reduce yield. Recent solutions can involve using smaller integrated circuits interconnected with a semiconductor interposer or integrated with silicon bridges assembled into a silicon substrate to provide a heterogeneous-chip package. However, conventional techniques for making the semiconductor imposer or substrate limit the size of the heterogeneous-chip package.

### BRIEF DESCRIPTION OF THE DRAWINGS

In the drawings, which are not necessarily drawn to scale, like numerals may describe similar components in different views. Like numerals having different letter suffixes may represent different instances of similar components. Some embodiments are illustrated by way of example, and not limitation, in the figures of the accompanying drawings in which:

FIG. 1 illustrates generally an example of at least a portion of a heterogeneous-chip package 100 according to the present subject matter.

FIGS. 2A-2G illustrates a method of fabricating a heterogeneous-chip package 100 according to the present subject matter.

FIG. 3 illustrates a flowchart of a method 300 for making a heterogeneous-chip package.

FIG. 4 illustrates a block diagram of an example machine 400 upon which any one or more of the techniques (e.g., methodologies) discussed herein may perform.

FIG. 5 illustrates a system level diagram, depicting an example of an electronic device (e.g., system) including a heterogeneous-chip package as described in the present disclosure.

### DETAILED DESCRIPTION

The following description and the drawings sufficiently illustrate specific embodiments to enable those skilled in the art to practice them. Other embodiments may incorporate structural, logical, electrical, process, and other changes. Portions and features of some embodiments may be included in, or substituted for, those of other embodiments. Embodiments set forth in the claims encompass all available equivalents of those claims.

Packaging techniques for using multiple heterogeneous dies in a single solution can require a number of die-to-die connections. Although a relatively new technology, a conventional solution to this challenge, which may be referred to as a 2.5D solution, can utilize a silicon interposer and Through Silicon Vias (TSVs) to connect die at so-called silicon interconnect speed in a minimal footprint. The result is increasingly complex layouts and manufacturing techniques that can delay tape-outs and depress yield rates. For example, some techniques that use a silicon interposer limit the size of the heterogeneous-chip package. One limitation is that the silicon interposer is limited to the lithographic reticle size of the fabrication process. A second limitation can be the ability of the assembly process to produce acceptable packages. For example, the assembly process can include mounting fine node die, or advanced node die, to the silicon interposer and then attaching the silicon interposer to a substrate such as an organic substrate. The attachment of the interposer to the substrate can involve a thermal connection bond (TCB) process that can warp the large interposer and not allow for robust electrical connections.

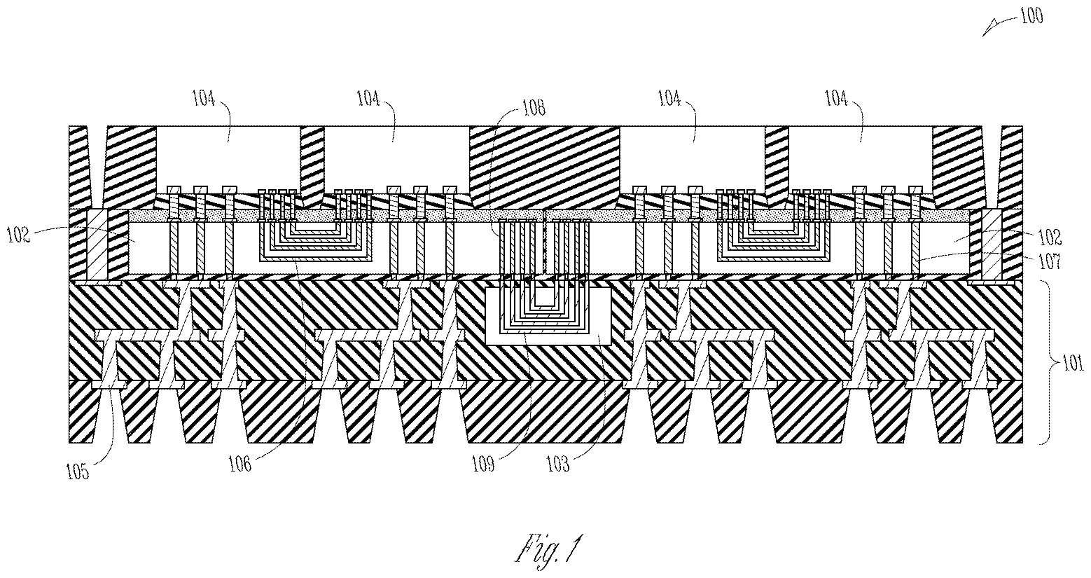

FIG. 1 illustrates generally an example of at least a portion of a heterogeneous-chip package 100 according to the present subject matter. In certain examples, the heterogeneous-chip package 100 can include a substrate 101, a plurality of base die 102, one or more silicon bridges 103 and one or more fine node chips 104. The substrate 101 can be an organic substrate and can include terminals or interconnections 105 for connecting the heterogeneous-chip package 100 to another device such as a printed circuit board or some other component of a larger electronic device. Each base die 102 can provide interconnections 106 for the fine node chips 104 connected thereon as well as some through interconnections 107 between a first side of the base die 102 and a second side of the base die 102. In certain examples, the base die 102 is passive and may or may not can include only passive circuit elements such as resistors, capacitors, inductors, diodes, etc. to support the fine node chips. In some examples, the base die 102 can include active components to support the fine node chips. In some examples, the base die 102 can include both passive components and active components to support the operation of the fine node chips 104 or the operation for the heterogeneous-chip package 100. Circuits of the base die 102 can include, but are not limited to, voltage converters, level shifters, buffers, clock circuits, etc. In certain examples, the size of the base die circuits can be limited by the reticle size of the lithography equipment used for manufacturing the base die 102. In certain examples, the base die 102 can include additional interconnections 108 for coupling to other base die via a silicon bridge 103.

The silicon bridges 103 can be manufactured using the same wafer fabrication processes used to fabricate the base die 102 or the fine node chips 104. In certain aspects, a silicon bridge can be characterized by its small size, thinness and fine routing. For example, length and width of a silicon bridge can be a combination of 2 mm, 4 mm, 6 mm and even larger in some circumstances. A silicon bridge can have trace routings of 2 micrometer (um) width and 2 um spacing. Silicon bridges generally have a thickness of between 35 um and 150 um but can be thicker depending upon the application. In certain examples, a silicon bridge can include at least two ground layers of conductive material and two routing layers of conductive material. Silicon bridges 103 can provide interconnections 109 between small node spacing of the base die 102 and can allow the overall size of the heterogeneous-chip package 100 to become quite large while providing yields not available with conventionally assembled heterogeneous-chip packages that include fine node chips. Fine node chips 104 can include node spacing on the order of 12 nm, 10 nm, 7 nm and finer, but are not limited as such. As transistor pitch technology develops to address node length smaller than 7 nm, the present subject matter is anticipated to allow fabrication or assembly of heterogeneous-chip packages that are not limited by the reticle area available for making a monolithic interposer or base die 102. Accordingly, large heterogeneous-chip packages using fine node chips can be fabricated with robust yields using inexpensive, large panel, organic substrate based processing. In certain examples, interconnected base die of a heterogeneous-chip package utilizing 7 nm fine node chips can define a final package having a width, length, or combination thereof, of 25 mm, 50 mm, 75 mm or longer and still maintain high yields.

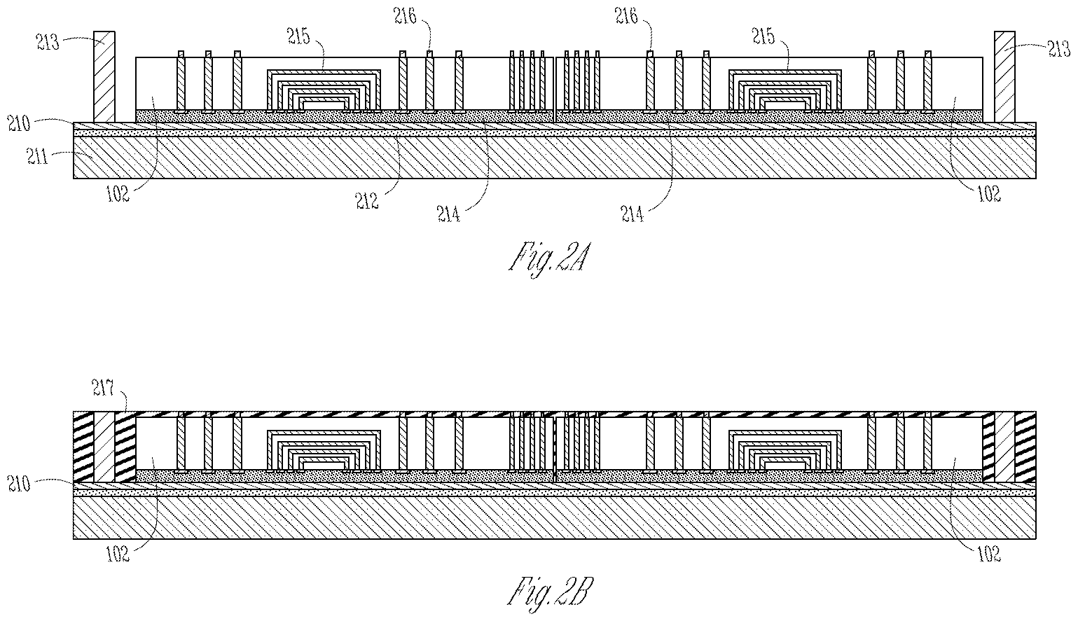

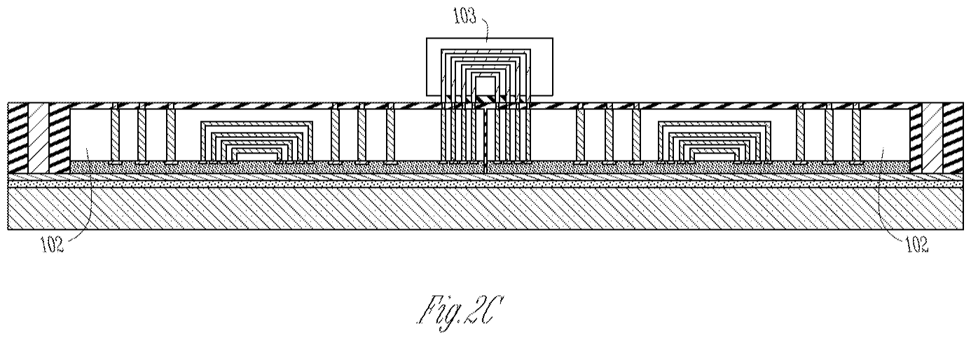

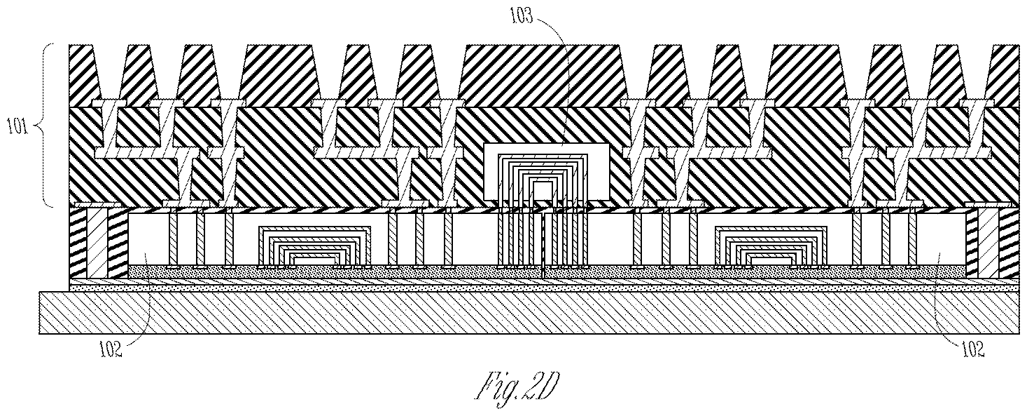

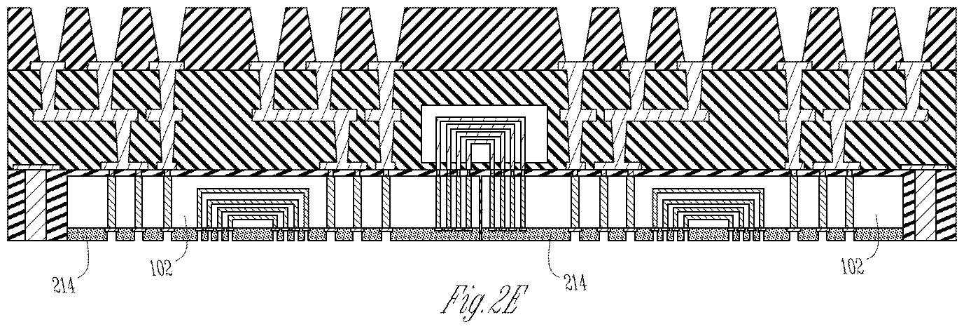

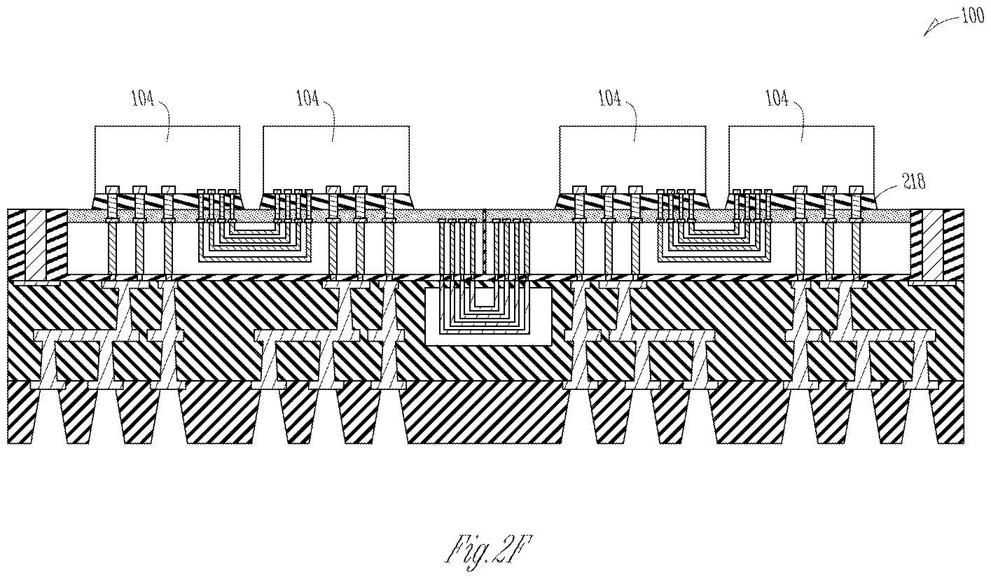

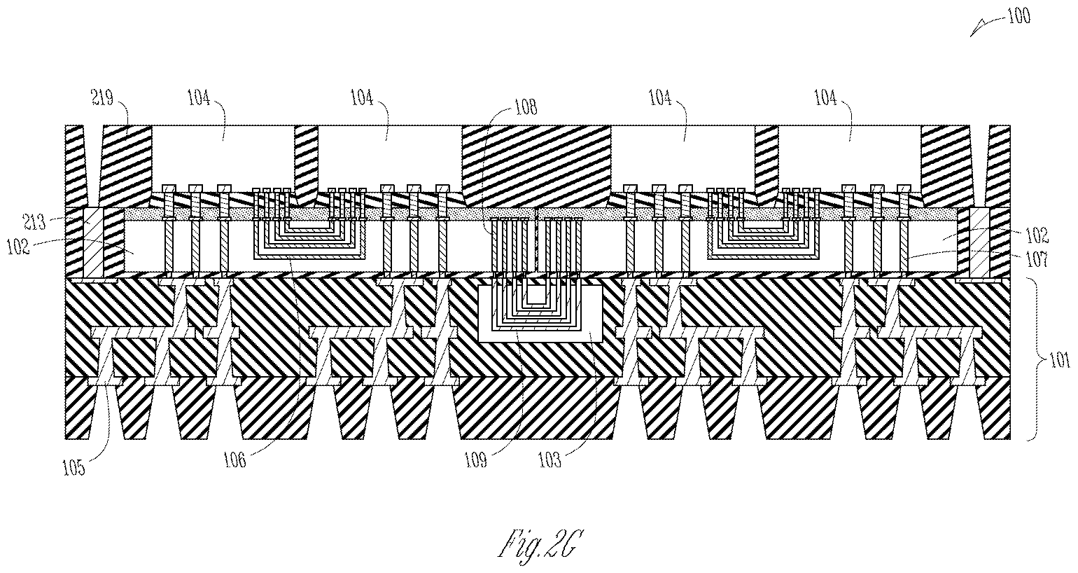

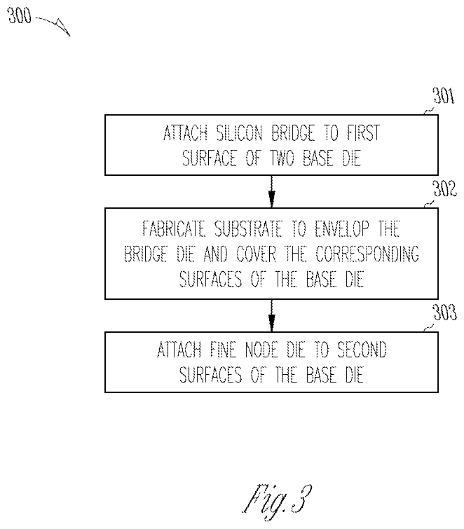

FIGS. 2A-2G illustrates a method of fabricating a heterogeneous-chip package 100 according to the present subject matter. FIG. 2A shows a seed layer 210 attached to a removeable fabrication substrate 211, or fabrication carrier. In certain examples, the seed layer 210 can be deposited on a release agent or releasable adhesive 212. The seed layer 210 can be used to build up metal posts 213 that can serve as fiducials for accurately placing two or more base die 102 between the posts 213. The posts 213 can be fabricated using conventional methods. In certain examples, the metal posts can provide a functional connection between the major surfaces of the heterogeneous-chip package 100, for example, for stacking the heterogeneous-chip package 100 with other components.

The base die 102 can be positioned and attached to the seed layer 210 using conventional methods. In certain examples, the base die 102 can be attached to the seed layer using a second adhesive 214. In certain examples, the fabrication substrate 211 is a dimensional stable substrate such as glass. As discussed above, each base die 102 can provide first interconnections 215 for the fine node chips 104 connected thereon as well as some through connections 216 between a first side of the base die 102 and a second side of the base die 102.

At FIG. 2B, after the base die 102 are placed on the seed layer 210, a dielectric material 217 can be fabricated, such as by molding, to cover the base die 102. The dielectric material 217 can then be ground or etched to reveal the connections on the first sides of each base die 102. At FIG. 2C, a silicon bridge 103 can be mounted and electrically connected between two base die 102. The silicon bridge 103 can provide interconnections between the base die 102. The use of a dimensionally stable carrier or fabrication substrate 211, such as glass, and the attach of silicon bridge 103 in the very initial stages of the process can provide an opportunity for significantly higher placement accuracy and interconnection reliability than in the conventional silicon bridge embedding processes where the bridge is placed in the final stages of the substrate processing and on a dimensionally less stable multi-layer organic substrate.

At FIG. 2D, a substrate 101, such as an organic substrate, can be manufactured to envelop the exposed sides of the silicon bridge 103 and to provide external connections of the base dies 102. At FIG. 2E, the fabrication substrate 211 can be removed along with the releasable adhesive 212, the seed layer 210 can be etched or removed, and the second adhesive 214 can be etched or drilled to expose terminations on a second side of the base die 102. In certain examples, the intermediate assembly of the heterogeneous-chip can be flipped either before or after the fabrication substrate 211 is removed.

At FIG. 2F, fine node die 104 can be attached to each base die 102. In certain examples, the fine node die 104 are electrically connected, via fabricated interconnections 220, to the terminations on the second side of each base die 102 and then underfilled 218. At FIG. 2G, a second dielectric 219 can be fabricated to cover the fine node die 104. The second dielectric 219 can be grinded to expose the backside of the fine node die 104 for heat dissipation. In certain examples, an Integrated Heat Spreader (IHS) (not shown) can be attached for enhanced heat dissipation. In certain examples, the second dielectric 219 can be drilled to expose terminations of one or more of the fiducial posts 213. Additional fabrication can involve depositing conductive material to form pads or bumps to allow the heterogeneous-chip package to be electrically connected to another component such as, but not limited to, a printed circuit board. In certain examples, FIGS. 2A-2G illustrate fabrication of a heterogeneous-chip having two base die and a single silicon bridge. In certain examples, FIGS. 2A-2G illustrate fabrication of a portion of a larger heterogeneous-chip package. It is understood that a heterogeneous-chip package using the above methods can include many more base die and silicon bridges without departing from the scope of the present subject matter.

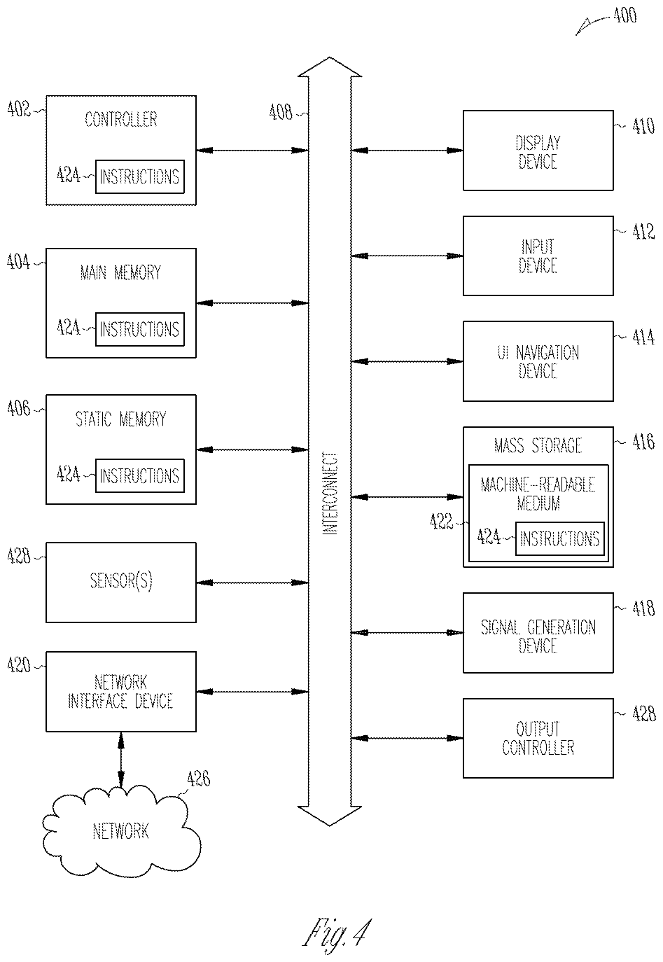

FIG. 3 illustrates a flowchart of a method 300 for making a heterogeneous-chip package. At 301, a silicon bridge can be attached to two base die to facilitate electrical interconnections between the base die. In certain examples, the bridge die can be a very thin silicon die with traces coupling external terminations, such as external micro-bump terminations with pitch spacing on the order of 55 micrometer, 35 micrometer, future smaller pitches such as 10 micrometer, or combinations thereof. At 302, a substrate can be fabricated to envelop the silicon bridge and to cover the corresponding surfaces of the base die. As used herewith, fabricating the substrate does not include assembling a pre-made substrate with the assembled base die and silicon bridge. Fabricating in this instance, as well as with respect to FIG. 2D, includes depositing one or more layers of materials on the assembly of the base die and bridge die such that as the substrate is fabricated, the substrate conforms to the topography of the surface of the base die coupled to the silicon bridge and to the topology of the exposed portions of the silicon bridge. In certain examples, upon completion of the substrate, the silicon bridge can be enveloped within the substrate except for the surface of the bridge die coupled to the base die. In certain examples, the substrate can be an organic substrate. In certain examples, fabricating the substrate can be done in layers to allow for conductive layers and vias to be fabricated and formed. The conductive layers and vias of the substrate can allow the pitch of the base die to be fanned out to an acceptable pitch for external terminations of the heterogeneous-chip package.

In certain examples, the method 300 can include fabricating a fiducial marker on a stable fabrication substrate. Such markers can be used to position the base die with respect to each other such that the external connections of the base die are properly positioned for interconnection via the bridge die. In certain examples, the fiducial markers can be formed of metal upon a seed layer attached to the stable fabrication substrate. In some examples, the fiducial markers can be metal posts extending perpendicular to the fabrication substrate. In certain examples, upon fabricating the substrate over the bridge die and corresponding surfaces of the base die, the fabrication substrate can be removed and, at 303, nodes of fine node die can be attached to corresponding nodes of the base die on surfaces of the base die opposite the surfaces of the based die to which the silicon bridge is attached.

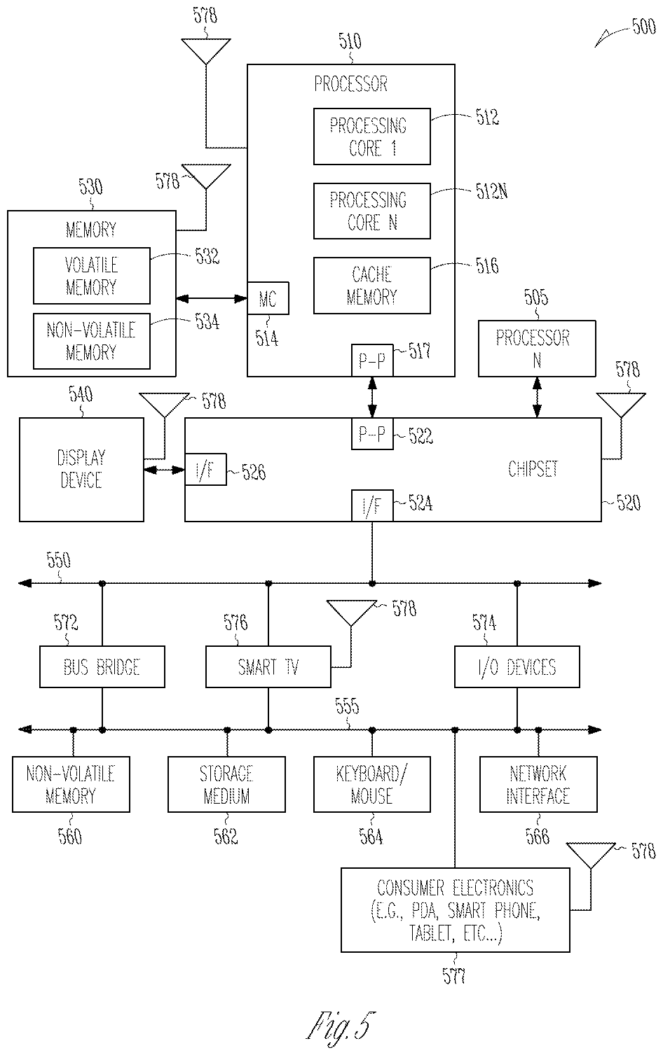

FIG. 4 illustrates a block diagram of an example machine 400 upon which any one or more of the techniques (e.g., methodologies) discussed herein may perform. In alternative embodiments, the machine 400 may operate as a standalone device or may be connected (e.g., networked) to other machines. In a networked deployment, the machine 400 may operate in the capacity of a server machine, a client machine, or both in server-client network environments. In an example, the machine 400 may act as a peer machine in peer-to-peer (or other distributed) network environment. As used herein, peer-to-peer refers to a data link directly between two devices (e.g., it is not a hub- and spoke topology). Accordingly, peer-to-peer networking is networking to a set of machines using peer-to-peer data links. The machine 400 may be a single-board computer, an integrated circuit package, a system-on-a-chip (SOC), a personal computer (PC), a tablet PC, a set-top box (STB), a personal digital assistant (PDA), a mobile telephone, a web appliance, a network router, or other machine capable of executing instructions (sequential or otherwise) that specify actions to be taken by that machine. Further, while only a single machine is illustrated, the term “machine” shall also be taken to include any collection of machines that individually or jointly execute a set (or multiple sets) of instructions to perform any one or more of the methodologies discussed herein, such as cloud computing, software as a service (SaaS), other computer cluster configurations.

Examples, as described herein, may include, or may operate by, logic or a number of components, or mechanisms. Circuitry is a collection of circuits implemented in tangible entities that include hardware (e.g., simple circuits, gates, logic, etc.). Circuitry membership may be flexible over time and underlying hardware variability. Circuitries include members that may, alone or in combination, perform specified operations when operating. In an example, hardware of the circuitry may be immutably designed to carry out a specific operation (e.g., hardwired). In an example, the hardware of the circuitry may include variably connected physical components (e.g., execution units, transistors, simple circuits, etc.) including a computer readable medium physically modified (e.g., magnetically, electrically, moveable placement of invariant massed particles, etc.) to encode instructions of the specific operation. In connecting the physical components, the underlying electrical properties of a hardware constituent are changed, for example, from an insulator to a conductor or vice versa. The instructions enable embedded hardware (e.g., the execution units or a loading mechanism) to create members of the circuitry in hardware via the variable connections to carry out portions of the specific operation when in operation. Accordingly, the computer readable medium is communicatively coupled to the other components of the circuitry when the device is operating. In an example, any of the physical components may be used in more than one member of more than one circuitry. For example, under operation, execution units may be used in a first circuit of a first circuitry at one point in time and reused by a second circuit in the first circuitry, or by a third circuit in a second circuitry at a different time.

Machine (e.g., computer system) 400 may include a hardware processor 402 (e.g., a central processing unit (CPU), a graphics processing unit (GPU), a hardware processor core, a heterogeneous-chip package, or any combination thereof), a main memory 404 and a static memory 406, some or all of which may communicate with each other via an interlink (e.g., bus) 408. The machine 400 may further include a display unit 410, an alphanumeric input device 412 (e.g., a keyboard), and a user interface (UI) navigation device 414 (e.g., a mouse). In an example, the display unit 410, input device 412 and UI navigation device 414 may be a touch screen display. The machine 400 may additionally include a storage device (e.g., drive unit) 416, a signal generation device 418 (e.g., a speaker), a network interface device 420, and one or more sensors 421, such as a global positioning system (GPS) sensor, compass, accelerometer, or other sensor. The machine 400 may include an output controller 428, such as a serial (e.g., universal serial bus (USB), parallel, or other wired or wireless (e.g., infrared (IR), near field communication (NFC), etc.) connection to communicate or control one or more peripheral devices (e.g., a printer, card reader, etc.).

The storage device 416 may include a machine readable medium 422 on which is stored one or more sets of data structures or instructions 424 (e.g., software) embodying or utilized by any one or more of the techniques or functions described herein. The instructions 424 may also reside, completely or at least partially, within the main memory 404, within static memory 406, or within the hardware processor 402 during execution thereof by the machine 400. In an example, one or any combination of the hardware processor 402, the main memory 404, the static memory 406, a heterogeneous-chip package, or the storage device 416 may constitute machine readable media. In certain examples, such as, but not limited to, a server machine, a heterogeneous-chip package can include the machine 400 or any combination of the above mentioned components 402.

While the machine readable medium 422 is illustrated as a single medium, the term “machine readable medium” may include a single medium or multiple media (e.g., a centralized or distributed database, and/or associated caches and servers) configured to store the one or more instructions 424.

The term “machine readable medium” may include any medium that is capable of storing, encoding, or carrying instructions for execution by the machine 400 and that cause the machine 400 to perform any one or more of the techniques of the present disclosure, or that is capable of storing, encoding or carrying data structures used by or associated with such instructions. Non-limiting machine readable medium examples may include solid-state memories, and optical and magnetic media. In an example, a massed machine readable medium comprises a machine readable medium with a plurality of particles having invariant (e.g., rest) mass. Accordingly, massed machine-readable media are not transitory propagating signals. Specific examples of massed machine readable media may include: non-volatile memory, such as semiconductor memory devices (e.g., Electrically Programmable Read-Only Memory (EPROM), Electrically Erasable Programmable Read-Only Memory (EEPROM)) and flash memory devices; magnetic disks, such as internal hard disks and removable disks; magneto-optical disks; and CD-ROM and DVD-ROM disks.

The instructions 424 may further be transmitted or received over a communications network 426 using a transmission medium via the network interface device 420 utilizing any one of a number of transfer protocols (e.g., frame relay, internet protocol (IP), transmission control protocol (TCP), user datagram protocol (UDP), hypertext transfer protocol (HTTP), etc.). Example communication networks may include a local area network (LAN), a wide area network (WAN), a packet data network (e.g., the Internet), mobile telephone networks (e.g., cellular networks), Plain Old Telephone (POTS) networks, and wireless data networks (e.g., Institute of Electrical and Electronics Engineers (IEEE) 802.11 family of standards known as Wi-Fi®, IEEE 802.16 family of standards known as WiMax®), IEEE 802.15.4 family of standards, peer-to-peer (P2P) networks, among others. In an example, the network interface device 420 may include one or more physical jacks (e.g., Ethernet, coaxial, or phone jacks) or one or more antennas to connect to the communications network 426. In an example, the network interface device 420 may include a plurality of antennas to wirelessly communicate using at least one of single-input multiple-output (SIMO), multiple-input multiple-output (MIMO), or multiple-input single-output (MISO) techniques. The term “transmission medium” shall be taken to include any intangible medium that is capable of storing, encoding or carrying instructions for execution by the machine 400, and includes digital or analog communications signals or other intangible medium to facilitate communication of such software.

FIG. 5 illustrates a system level diagram, depicting an example of an electronic device (e.g., system) that can include a heterogeneous-chip package as described in the present disclosure. In one embodiment, system 500 includes, but is not limited to, a desktop computer, a laptop computer, a netbook, a tablet, a notebook computer, a personal digital assistant (PDA), a server, a workstation, a cellular telephone, a mobile computing device, a smart phone, an Internet appliance or any other type of computing device. In some embodiments, system 500 is a system on a chip (SOC) system.

In one embodiment, processor 510 has one or more processor cores 512 and 512N, where 512N represents the Nth processor core inside processor 510 where N is a positive integer. In one embodiment, system 500 includes multiple processors including 510 and 505, where processor 505 has logic similar or identical to the logic of processor 510. In some embodiments, processing core 512 includes, but is not limited to, pre-fetch logic to fetch instructions, decode logic to decode the instructions, execution logic to execute instructions and the like. In some embodiments, processor 510 has a cache memory 516 to cache instructions and/or data for system 500. Cache memory 516 may be organized into a hierarchal structure including one or more levels of cache memory.

In some embodiments, processor 510 includes a memory controller 514, which is operable to perform functions that enable the processor 510 to access and communicate with memory 530 that includes a volatile memory 532 and/or a non-volatile memory 534. In some embodiments, processor 510 is coupled with memory 530 and chipset 520. Processor 510 may also be coupled to a wireless antenna 578 to communicate with any device configured to transmit and/or receive wireless signals. In one embodiment, an interface for wireless antenna 578 operates in accordance with, but is not limited to, the IEEE 802.11 standard and its related family, Home Plug AV (HPAV), Ultra Wide Band (UWB), Bluetooth, WiMax, or any form of wireless communication protocol.

In some embodiments, volatile memory 532 includes, but is not limited to, Synchronous Dynamic Random Access Memory (SDRAM), Dynamic Random Access Memory (DRAM), RAMBUS Dynamic Random Access Memory (RDRAM), and/or any other type of random access memory device. Non-volatile memory 534 includes, but is not limited to, flash memory, phase change memory (PCM), read-only memory (ROM), electrically erasable programmable read-only memory (EEPROM), or any other type of non-volatile memory device.

Memory 530 stores information and instructions to be executed by processor 510. In one embodiment, memory 530 may also store temporary variables or other intermediate information while processor 510 is executing instructions. In the illustrated embodiment, chipset 520 connects with processor 510 via Point-to-Point (PtP or P-P) interfaces 517 and 522. Chipset 520 enables processor 510 to connect to other elements in system 500. In some embodiments of the example system, interfaces 517 and 522 operate in accordance with a PtP communication protocol such as the Intel® QuickPath Interconnect (QPI) or the like. In other embodiments, a different interconnect may be used. In certain examples, a heterogeneous-chip package, as discussed above with reference to FIGS. 1, 2A-2g and 3, can include processor 510, memory 530, chipset 520, interface 517, interface 522, or combinations thereof.

In some embodiments, chipset 520 is operable to communicate with processor 510, 505N, display device 540, and other devices, including a bus bridge 572, a smart TV 576, I/O devices 574, nonvolatile memory 560, a storage medium (such as one or more mass storage devices) 562, a keyboard/mouse 564, a network interface 566, and various forms of consumer electronics 577 (such as a PDA, smart phone, tablet etc.), etc. In one embodiment, chipset 520 couples with these devices through an interface 524. Chipset 520 may also be coupled to a wireless antenna 578 to communicate with any device configured to transmit and/or receive wireless signals.

Chipset 520 connects to display device 540 via interface 526. Display 540 may be, for example, a liquid crystal display (LCD), a plasma display, cathode ray tube (CRT) display, or any other form of visual display device. In some embodiments of the example system, processor 510 and chipset 520 are merged into a single SOC. In addition, chipset 520 connects to one or more buses 550 and 555 that interconnect various system elements, such as I/O devices 574, nonvolatile memory 560, storage medium 562, a keyboard/mouse 564, and network interface 566. Buses 550 and 555 may be interconnected together via a bus bridge 572.

In one embodiment, mass storage device 562 includes, but is not limited to, a solid state drive, a hard disk drive, a universal serial bus flash memory drive, or any other form of computer data storage medium. In one embodiment, network interface 566 is implemented by any type of well-known network interface standard including, but not limited to, an Ethernet interface, a universal serial bus (USB) interface, a Peripheral Component Interconnect (PCI) Express interface, a wireless interface and/or any other suitable type of interface. In one embodiment, the wireless interface operates in accordance with, but is not limited to, the IEEE 802.11 standard and its related family, Home Plug AV (HPAV), Ultra Wide Band (UWB), Bluetooth, WiMax, or any form of wireless communication protocol.

While the modules shown in FIG. 5 are depicted as separate blocks within the system 500, the functions performed by some of these blocks may be integrated within a single semiconductor circuit or may be implemented using two or more separate integrated circuits. For example, although cache memory 516 is depicted as a separate block within processor 510, cache memory 516 (or selected aspects of 516) can be incorporated into processor core 512.

### Additional Notes

In a first example, Example 1, a method of forming a heterogeneous-chip package can include coupling electrical terminals of a first side of a first base die to electrical terminals of a first side of a second base die using a silicon bridge, forming an organic substrate about the silicon bridge and adjacent the first sides of the first and second base dies, and coupling an advanced node die to a second side of at least one of the first base die or the second base die.

In Example 2, the method of claim 1 optionally includes, prior to coupling the electrical terminals of the first side of the first base die to the electrical terminals of the first side of the second base die using the silicon bridge, attaching the second side of the first base die to a carrier, and attaching the second side of the second base die to the carrier.

In Example 3, the carrier of any one or more of Examples 1-2 optionally is a glass-based carrier.

In Example 4, the method of any one or more of Examples 1-3 optionally includes, prior to pacing either the first base die or the second base die on the carrier, fabricating fiducial markers on the carrier to assist with placement of the first base die and second base die.

In Example 5, the fabricating the fiducial markers of any one or more of Examples 1-4 optionally includes depositing a seed layer on the carrier, and fabricating the fiducial markers on the seed layer.

In Example 6, the fiducial markers of any one or more of Examples 1-5 optionally are configured to assist with placement of more than two base die on the carrier.

In Example 7, the method of any one or more of Examples 1-6 optionally includes, prior to coupling the electrical terminals of the first side of the first base die to the electrical terminals of the first side of the second base die using the silicon bridge, over-molding the first and second base die with a dielectric material.

In Example 8, the method of any one or more of Examples 1-2 optionally includes grinding the dielectric material to expose the electrical terminals of the first side of the first base die.

In Example 9, the method of any one or more of Examples 1-8 optionally includes grinding the dielectric material to expose the electrical terminals of the first side of the second base die.

In Example 10, the method of any one or more of Examples 1-2 optionally includes removing the carrier after forming the organic substrate.

In Example 11, the method of any one or more of Examples 1-2 optionally includes etching an adhesive adjacent the second side of the first base die and a second side of the second base die to expose electrical terminals of the second side of the first base die and to expose electrical terminals of the second side of the second base die.

In Example 12, the method of any one or more of Examples 1-11 optionally includes underfilling the advanced node die.

In Example 13, the method of any one or more of Examples 1-2 optionally includes over-molding the advanced node die.

In Example 14, a heterogeneous-chip package can include a first base die, a second base die, a silicon bridge configured to couple terminals of a first side of the first base die with terminals of a first side of the second base die, an organic substrate disposed about the silicon bridge and adjacent the first side of the first and second base dies, the organic substrate configured to provide electrical terminals for coupling the heterogeneous-chip package to a circuit, and an advanced node die coupled to electrical connections of a second side of one of the first base die or the second base die.

In Example 15, the first base die of any one or more of Examples 1-14 optionally is configured to connect second terminals of the first side of the first base die with second terminals of the second side of the first base die.

In Example 16, the second base die of any one or more of Examples 1-15 optionally is configured to connect second terminals of the first side of the second base die with second terminals of the second side of the second base die.

In Example 17, an area of a footprint of the heterogeneous-chip package of any one or more of Examples 1-16 optionally is larger than 700 mm² and the advance node die includes 7 nm technology.

In Example 18, the heterogeneous-chip package of any one or more of Examples 1-17 optionally includes a length dimension of greater than 50 mm.

In Example 19, the heterogeneous-chip package of any one or more of Examples 1-18 optionally includes a width dimension of greater than 50 mm.

In Example 20, the heterogeneous-chip package of any one or more of Examples 1-19 optionally includes additional base die supporting connections of additional fine node die, the additional base die interconnected with each other via first additional silicon bridges and interconnected with the first base die and the second base die via second additional silicon bridges.

The above detailed description includes references to the accompanying drawings, which form a part of the detailed description. The drawings show, by way of illustration, specific embodiments in which the invention can be practiced. These embodiments are also referred to herein as “examples.” Such examples can include elements in addition to those shown or described. However, the present inventors also contemplate examples in which only those elements shown or described are provided. Moreover, the present inventors also contemplate examples using any combination or permutation of those elements shown or described (or one or more aspects thereof), either with respect to a particular example (or one or more aspects thereof), or with respect to other examples (or one or more aspects thereof) shown or described herein.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In this document, the terms “including” and “in which” are used as the plain-English equivalents of the respective terms “comprising” and “wherein.” Also, in the following claims, the terms “including” and “comprising” are open-ended, that is, a system, device, article, composition, formulation, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

The above description is intended to be illustrative, and not restrictive. For example, the above-described examples (or one or more aspects thereof) may be used in combination with each other. Other embodiments can be used, such as by one of ordinary skill in the art upon reviewing the above description. The Abstract is provided to comply with 37 C.F.R. § 1.72(b), to allow the reader to quickly ascertain the nature of the technical disclosure. It is submitted with the understanding that it will not be used to interpret or limit the scope or meaning of the claims. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed embodiment. Thus, the following claims are hereby incorporated into the Detailed Description, with each claim standing on its own as a separate embodiment, and it is contemplated that such embodiments can be combined with each other in various combinations or permutations. The scope of the invention should be determined with reference to the appended claims, along with the full scope of equivalents to which such claims are legally entitled.

What is claimed is:

1. A chip package, comprising:
a base die in a molding material, the base die comprising interconnections;
a metal post in the molding material, the metal post laterally adjacent to the base die;
a first chip electrically coupled to the base die;
a second chip electrically coupled to the base die, the second chip electrically coupled to the first chip by the interconnections in the base die; and
a dielectric material between and in contact with the first chip and the second chip, the dielectric material having an upper surface co-planer with an upper surface of the first chip.

2. The chip package of claim 1, wherein the metal post is a fiducial.

3. The chip package of claim 1, wherein the base die comprises a plurality of through interconnections.

4. The chip package of claim 1, wherein the base die is a passive die.

5. The chip package of claim 1, wherein the base die is an active die.

6. The chip package of claim 5, wherein the first chip has a transistor pitch less than a transistor pitch of the base die.

7. The chip package of claim 1, wherein the upper surface of the dielectric material is co-planar with an upper surface of the second chip.

8. The chip package of claim 1, wherein the first chip and the second chip are entirely within a footprint of the base die.

9. The chip package of claim 1, wherein the first chip is a first node chip, and the second chip is a second node chip.

10. The chip package of claim 1, further comprising:
a plurality of conductive interconnections beneath the base die.

11. A chip package, comprising:
a base die in a molding material, the base die comprising interconnections;
a metal post in the molding material, the metal post laterally adjacent to the base die;
a first chip electrically coupled to the base die;
a second chip electrically coupled to the base die, the second chip electrically coupled to the first chip by the interconnections in the base die;
an underfill material between the first chip and the base die and between the second chip and the base die; and
a dielectric material laterally adjacent to the first chip and the second chip.

12. The chip package of claim 11, wherein the metal post is a fiducial.

13. The chip package of claim 11, wherein the base die comprises a plurality of through interconnections.

14. The chip package of claim 11, wherein the base die is a passive die.

15. The chip package of claim 11, wherein the base die is an active die.

16. The chip package of claim 15, wherein the first chip has a transistor pitch less than a transistor pitch of the base die.

17. The chip package of claim 11, wherein the dielectric material has an upper surface co-planer with an upper surface of the first chip.

18. The chip package of claim 17, wherein the upper surface of the dielectric material is co-planar with an upper surface of the second chip.

19. The chip package of claim 11, wherein the first chip and the second chip are entirely within a footprint of the base die.

20. The chip package of claim 11, wherein the first chip is a first node chip, and the second chip is a second node chip.

21. The chip package of claim 11, further comprising:
a plurality of conductive interconnections beneath the base die.

22. A multi-chip package, comprising:
a base die in and contacting a molding material, the base die comprising interconnections, the base die comprising through interconnections, and the base die comprising active components;
a metal post in and contacting the molding material, the metal post laterally adjacent to the base die;
a first chip electrically coupled to the base die;
a second chip electrically coupled to the base die, the second chip electrically coupled to the first chip by the interconnections in the base die; and
a dielectric material between and in contact with the first chip and the second chip.

23. The multi-chip package of claim 22, wherein the dielectric material has an upper surface co-planer with an upper surface of the first chip.

24. The multi-chip package of claim 23, wherein the upper surface co-planer of the dielectric material is co-planar with an upper surface of the second chip.

25. The multi-chip package of claim 22, wherein the dielectric material is further along outermost sides of the first chip and the second chip.

26. The multi-chip package of claim 22, wherein the metal post is a fiducial.

27. The multi-chip package of claim 22, wherein the first chip has a transistor pitch less than a transistor pitch of the base die.

28. The multi-chip package of claim 27, wherein the second chip has a transistor pitch less than the transistor pitch of the base die.

29. The multi-chip package of claim 22, wherein the first chip is entirely within a footprint of the base die.

30. The multi-chip package of claim 29, wherein the second chip is entirely within the footprint of the base die.

31. The multi-chip package of claim 22, wherein the first chip is a first node chip, and the second chip is a second node chip.

32. The multi-chip package of claim 22, further comprising:
a plurality of conductive interconnections beneath the base die.

33. A multi-chip package, comprising:
a base die having a top surface, a bottom surface, a first side and a second side, the second side opposite the first side, the base die comprising interconnections, and the base die comprising through interconnections;
a molding material laterally adjacent to the base die, the molding material in direct contact with the first side and the second side of the base die;
a metal post in and in direct contact with the molding material, the metal post laterally spaced apart from the first side of the base die;
a first chip electrically coupled to the base die;
a second chip electrically coupled to the base die, the second chip electrically coupled to the first chip by the interconnections in the base die; and
a dielectric material between and in contact with the first chip and the second chip.

34. The multi-chip package of claim 33, wherein the base die comprises active components.

35. The multi-chip package of claim 33, wherein the dielectric material has an upper surface co-planer with an upper surface of the first chip.

36. The multi-chip package of claim 35, wherein the upper surface co-planer of the dielectric material is co-planar with an upper surface of the second chip.

37. The multi-chip package of claim 33, wherein the dielectric material is further along outermost sides of the first chip and the second chip.

38. The multi-chip package of claim 33, wherein the metal post is a fiducial.

39. The multi-chip package of claim 33, wherein the first chip has a transistor pitch less than a transistor pitch of the base die.

40. The multi-chip package of claim 39, wherein the second chip has a transistor pitch less than the transistor pitch of the base die.

41. The multi-chip package of claim 33, wherein the first chip is entirely within a footprint of the base die.

42. The multi-chip package of claim 41, wherein the second chip is entirely within the footprint of the base die.

43. The multi-chip package of claim 33, wherein the first chip is a first node chip, and the second chip is a second node chip.

44. The multi-chip package of claim 33, further comprising:
a plurality of conductive interconnections beneath the base die.
